(19) United States
(12) Patent Application Publication
(10) Pub. No.: US 2017/0322843 A1
(43) Pub. Date: Nov. 9, 2017

(54) MULTI-DIE DATA STORAGE DEVICE WITH IN-MEMORY PARITY CIRCUITRY

(71) Applicant: SANDISK TECHNOLOGIES INC., PLANO, TX (US)

(72) Inventors: HUA-LING CYNTHIA HSU, FREMONT, CA (US); ABHIJEET MANOHAR, BANGALORE (IN); DEEPANSHU DUTTA, FREMONT, CA (US)

(73) Assignee: SanDisk Technologies Inc.

(21) Appl. No.: 15/145,897

(22) Filed: May 4, 2016

(51) Int. Cl. G06F 11/10; G06F 3/06; G11C 29/52

(52) U.S. Cl. CPC G06F 11/1072; G11C 29/52; G06F 3/0688; G06F 3/0619; G06F 3/064; G06F 3/0647

(57) ABSTRACT

A data storage device includes a first memory die having memory cells and a first transfer data latch. The data storage device also includes a second memory die having second memory cells and a second transfer data latch. A bus is coupled to the first memory die and the second memory die. The data storage device also includes a controller coupled to the bus. The controller is configured to cause the first transfer data latch and the second transfer data latch to store first data responsive to sending the first data to the first memory die for programming of the first data to a first word line of the first memory cells.

### FIELD OF THE DISCLOSURE

The present disclosure is generally related to data storage devices with multiple memory dies and parity circuitry in the memory dies.

### BACKGROUND

Non-volatile data storage devices have enabled increased portability of data and software applications. For example, multi-level cell (MLC) storage elements of a flash memory device may each store multiple bits of data, enhancing data storage density as compared to single-level cell (SLC) flash memory devices. As another example, a memory with a three-dimensional (3D) memory configuration may include multiple layers of storage elements, thus increasing data storage density compared to a two-dimensional (2D) (or “planar”) memory device. Consequently, memory devices enable users to store and access a large amount of data.

Although quality testing is typically performed, it is impractical to attempt to eliminate all potential latent defects within each data storage device. Accordingly, data storage devices typically include extra blocks of memory that can be used as replacements for blocks of memory that fail after testing. While such extra blocks of memory help to preserve the total memory capacity of the data storage device if failures occur after testing, the extra blocks do not prevent loss of data if a failure occurs. For example, a failure of a particular word line may be detected after data is programmed to the word line and the content of the word line is read to verify the programming. If the content of the word line does not match the data programmed to the word line, this can indicate failure of the word line.

While the data programmed to the word line may be available to program to a backup location, such as a spare memory block, for certain types of failures, data stored in an adjacent word line may also be affected by the failure. For example, if the failure is due to a short between word lines, the content of the adjacent word line can be corrupted by the programming of the word line. Thus, to reduce the likelihood of data loss, both the word line being programmed and the adjacent word line should be reprogrammed to the backup location. A copy of the content of the adjacent word line may be stored in a volatile memory of a controller of the data storage device; however, volatile memory in the controller is expensive, so many controllers have limited volatile memory. Thus, the controller may not have sufficient volatile memory capacity to store data to be used for recovery of content already programmed to non-volatile memory (e.g., the content of the adjacent word line).

### BRIEF DESCRIPTION OF THE DRAWINGS

FIG. 1 is a block diagram of a particular illustrative aspects of a system that includes a data storage device having multiple memory dies configured to perform in-memory parity operations;

FIGS. 2A and 2B are a ladder diagram of illustrating particular aspects of operations to program a first word line of a first memory die of the data storage device of FIG. 1;

FIG. 2C is a ladder diagram of an illustrating particular aspects of operations to program a second word line of the first memory die of the data storage device of FIG. 1;

FIG. 2D is a ladder diagram of an illustrating particular aspects of operations to recover data of the first word line and the second word line following unsuccessful programming of the second word line of the first memory die of the data storage device of FIG. 1;

FIG. 3 is a block diagram of a particular illustrative aspects of mapping of word lines of a first memory die to corresponding parity data stored in data latches of other memory dies of the data storage device of FIG. 1;

FIG. 4 is a flow diagram of an illustrative method of operation of the data storage device of FIG. 1;

FIG. 5 is a block diagram of particular aspects of a memory device that may be included in the data storage device of FIG. 1; and

FIG. 6 is a block diagram of particular aspects of a memory device that may be included in the data storage device of FIG. 1.

### DETAILED DESCRIPTION

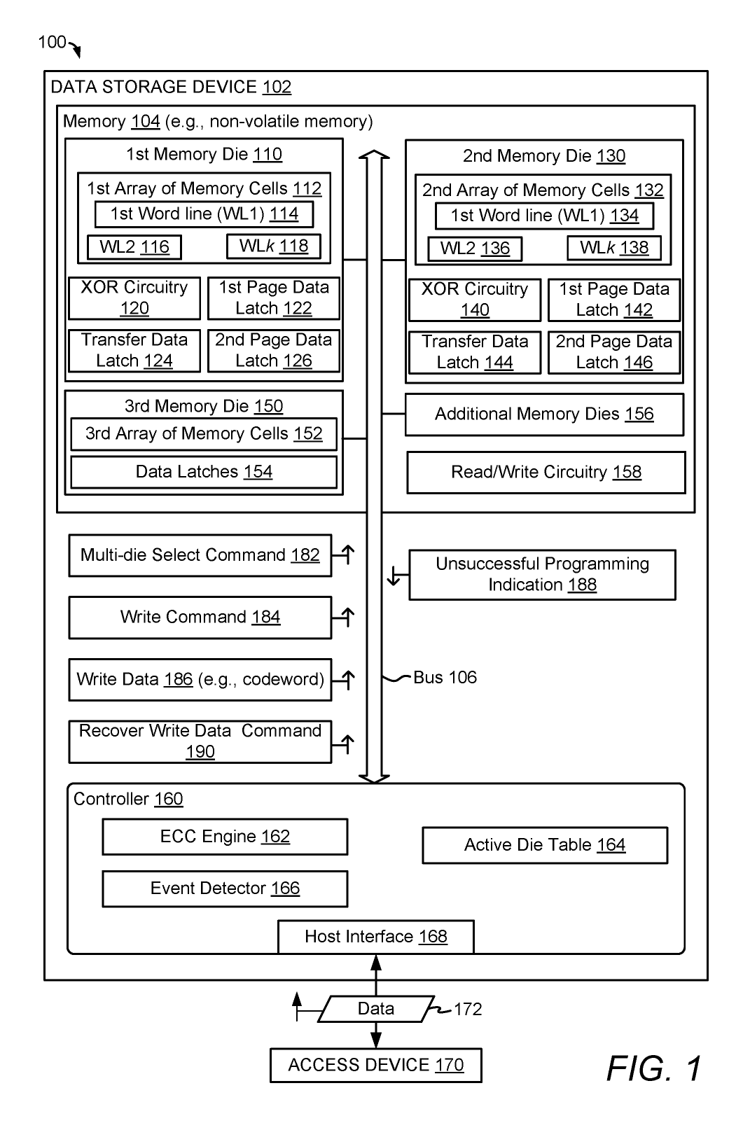

Referring to FIG. 1, an illustrative example of a system is depicted and generally designated 100. The system 100 includes a data storage device 102 and an access device 170. The data storage device 102 includes multiple memory dies that are configured to perform in-memory parity operations.

The data storage device 102 and the access device 170 may be operationally coupled via a connection, such as a bus or a wireless connection. The data storage device 102 may be embedded within the access device 170, such as in accordance with a Joint Electron Devices Engineering Council (JEDEC) Solid State Technology Association Universal Flash Storage (UFS) configuration. Alternatively, the data storage device 102 may be removable from the access device 170 (i.e., “removably” coupled to the access device 170). As an example, the data storage device 102 may be removably coupled to the access device 170 in accordance with a removable universal serial bus (USB) configuration. In an illustrative implementation, the data storage device 102 corresponds to a solid-state drive (SSD) that can be integrated within an electronic device, such as the access device 170.

The access device 170 may correspond to a mobile telephone, a computer (e.g., a laptop, a tablet, or a notebook computer), a music player, a video player, a gaming device or console, an electronic book reader, a personal digital assistant (PDA), a portable navigation device, another electronic device, or a combination thereof. The access device 170 may communicate via a host controller, which may enable the access device 170 to communicate with the data storage device 102. The access device 170 may operate in compliance with a JEDEC Solid State Technology Association industry specification, such as an embedded MultiMedia Card (eMMC) specification or a Universal Flash Storage (UFS) Host Controller Interface specification. The access device 170 may operate in compliance with one or more other specifications, such as a Secure Digital (SD) Host Controller specification as an illustrative example. Alternatively, the access device 170 may communicate with the data storage device 102 in accordance with another communication protocol.

The data storage device 102 includes a controller 160 and a memory 104 (e.g., non-volatile memory). The memory 104 may include a plurality of memory dies, including, for example, a first memory die 110, a second memory die 130, a third memory die 150, and one or more additional memory dies 156. The controller 160 may be coupled via a bus 106 to each of the memory dies 110, 130, 150, 156 of the memory 104.

The memory 104 may include a non-volatile memory, such as a NAND flash memory or a resistive random access memory (ReRAM). The memory 104 may have a three-dimensional (3D) memory configuration. For example, one or more of the memory dies 110, 130, 150, 156 may have a 3D memory configuration that is monolithically formed in one or more physical levels of arrays of memory cells having an active area disposed above a silicon substrate. Alternatively, the memory 104 may have another configuration, such as a two-dimensional (2D) memory configuration or a stacked 2D memory configuration.

Each of the memory dies 110, 130, 150, 156 may include one or more data latches and memory cells. For example, the first memory die 110 includes first memory cells, such as a first array of memory cells 112, including multiple word lines, such as a first word line (WL1) 114, a second word line (WL2) 116, and a kth word line (WLk) 118. The first memory die 110 also includes a set of data latches, including a transfer data latch 124, a first page data latch 122, and a second page data latch 126. Similarly, the second memory die 130 includes second memory cells, such as a second array of memory cells 132, including multiple word lines, such as a first word line (WL1) 134, a second word line (WL2) 136, and a kth word line (WLk) 138, and the second memory die 130 includes a set of data latches, including a transfer data latch 144, a first page data latch 142, and a second page data latch 146. The third memory die 150 includes third memory cells, such as a third array of memory cells 152 (which may include multiple word lines, not shown), and data latches 154. The additional memory dies 156 may also include arrays of memory cells and data latches (not shown). Although three data latches are illustrated in each of the first and second memory dies 110, 130, in some implementations, one or more of the memory dies 110, 130, 150, 156 may include more than three data latches. For example, in an implementation in which the memory 104 is configured to operate in a triple-level cell (TLC) configuration, the memory dies 110, 130, 150, 156 may each include three page data latches and at least one transfer data latch.

The memory dies 110, 130, 150, 156 may also include parity circuitry, such as exclusive-OR (XOR) circuitry 120, 140 configured to perform bitwise XOR operations. The memory 104 may also include read/write circuitry 158 which may be on a supplemental die, as illustrated in FIG. 1. Alternatively, each memory die 110, 130, 150, 156 may include its own read/write circuitry.

The memory 104 may correspond to a non-volatile memory that includes multiple blocks (e.g., erase groups of storage elements of the memory 104). Each of the blocks may include multiple word lines. For example, in FIG. 1, the first word line 114 and the second word line 116 may be part of a first block, and the kth word line 118 may be part of a different block. If a word line of a particular block fails during use, the particular block may be marked as unused, and data stored at the particular block may be moved to another block on the same memory die or on another memory die. It should be appreciated that the example of FIG. 1 is illustrative and that the memory 104 may include a different number of blocks and/or word lines than depicted in FIG. 1.

The controller 160 may include an error correcting code (ECC) engine 162 and an interface 168 (such as a host interface). The controller 160 is configured to receive data 172 and instructions from the access device 170 and to send data 172 to the access device 170. For example, the controller 160 may send the data 172 to the access device 170 via the interface 168 and may receive the data 172 from the access device 170 via the interface 168.

The ECC engine 162 is configured to generate one or more ECC codewords based on the data 172 received from the access device 170. The ECC engine 162 may include a Hamming encoder, a Reed-Solomon (RS) encoder, a Bose-Chaudhuri-Hocquenghem (BCH) encoder, a low-density parity check (LDPC) encoder, a turbo encoder, an encoder configured to encode data according to one or more other ECC schemes, or a combination thereof. The ECC engine 162 is also configured to decode data accessed from the memory 104. For example, the ECC engine 162 may be configured to decode data accessed from the memory 104 to detect and correct one or more errors that may be present in the data, up to an error correcting capacity of the particular ECC scheme. The ECC engine 162 may include a Hamming decoder, an RS decoder, a BCH decoder, an LDPC decoder, a turbo decoder, a decoder configured to decode data according to one or more other ECC schemes, or a combination thereof.

The controller 160 is configured to designate a first set of memory dies of the memory 104 as active memory dies and to designate a second set of memory dies of the memory 104 as inactive memory dies. For example, the controller 160 may maintain a table or other data structure, such as an active die table 164 that includes information identifying active memory dies. In other example, the controller 160 may maintain a table or other data structure that includes information identifying inactive memory dies. When the controller 160 has data to program to the memory 104, the controller 160 sends the data to an active memory die. When a particular active memory die is full (or stores a threshold quantity of data), the controller 160 may designate the particular memory die as inactive and may designate one of the inactive memory dies as active.

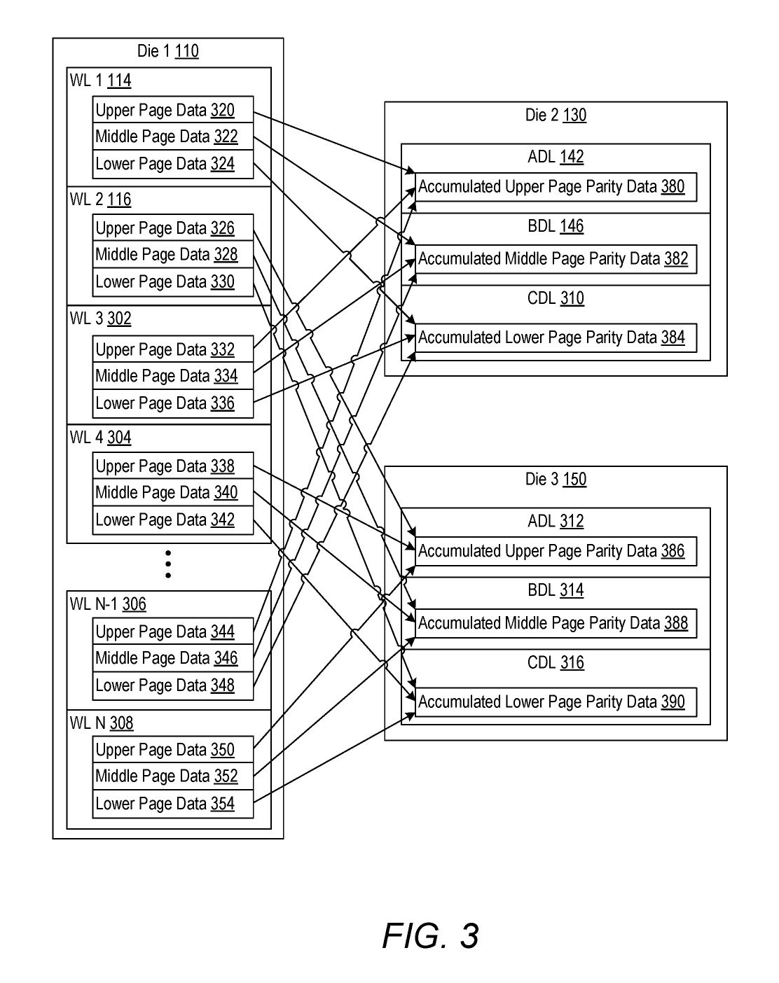

Thus, in a particular implementation, only a subset of the memory dies 110, 130, 150, 156 of the memory 104 are active at a particular time. In this implementation, data latches of inactive memory dies may be used to store parity data associated with data stored at the active memory dies. To illustrate, in the example of FIG. 1, the first memory die 110 may be active, and data latches of the second memory die 130, the third memory die 150, or both, may store parity data associated with data stored at the first memory die 110, as described further below. In some implementations, parity data for adjacent word lines may be stored at different inactive dies. To illustrate, parity data associated with odd-numbered word lines (e.g., the first word line 114) may be stored at the second memory die 130, and parity data associated with even-numbered word lines (e.g., the second word line 116) may be stored at the third memory die 150. FIG. 3 shows a particular example of mapping of word lines to inactive memory dies in greater detail.

The controller 160 is configured to send data (e.g., a codeword) and commands to the memory 104 and to receive data from the memory 104. For example, the controller 160 is configured to send write data 186 that is to be programmed to a particular word line of the memory 104 via the bus 106. The controller 160 is also configured to send a write command 184 to the memory 104 to cause the memory 104 to store the write data 186 to a specified address of the memory 104. The write command 184 may specify a physical address of a portion of the memory 104 (e.g., a physical address of a word line of a particular memory die) that is to store the write data 186. The controller 160 is also configured to send a read command (not shown) to the memory 104 to access data from a specified address of the memory 104. The read command may specify the physical address of a portion of the memory 104 (e.g., a physical address of a word line of the memory 104).

When the controller 160 sends the write data 186 to the memory 104, the transfer data latch of the memory die that is to store the write data 186 is activated (based on the write command 184) to enable the transfer data latch to store the write data 186. For example, when the write data 186 is to be stored at the first word line 114 of the first memory die 110, the write command 184 may include an address that identifies the first memory die 110 and the first word line 114. The controller 160 may send the write command 184 to the memory 104 via the bus 106, and the first memory die 110 may detect the address and activate the transfer data latch 124 of the first memory die 110 responsive to detecting the address. Thus, when the controller 160 sends the write data 186 via the bus 106 to the memory 104, the transfer data latch 124 is active to receive and store the write data 186.

In a particular implementation, the controller 160 is configured to also cause a transfer data latch of an inactive die to also receive and store the write data 186. For example, in FIG. 1, when the first memory die 110 is designated by the controller 160 as an active memory die (e.g., in the active die table 164) and the second memory die 130 is designated by the controller 160 as an inactive memory die (e.g., in the active die table 164), the controller 160 may send a multi-die select command 182 via the bus 106 to the memory 104. The multi-die select command 182 identifies one or more memory dies that are to receive and store write data despite not being addressed in a write command associated with the write data. To illustrate, continuing the example above in which the write command 184 identifies the first word line 114 of the first memory die 110, the controller 160 may send the multi-die select command 182 before sending the write command 184. The multi-die select command 182 may identify the second memory die 130. In this example, in response to the multi-die select command 182, the transfer data latch 144 of the second memory die 130 may be activated to receive the write data 186 even though the write command 184 associated with the write data 186 does not identify the second memory die 130.

After sending the multi-die select command 182, the controller 160 may send the write command 184 and the write data 186 via the bus 106. In this example, the transfer data latch 124 of the first memory die 110 may receive and store the write data 186, and the transfer data latch 144 of the second memory die 130 may also receive and store the write data 186. The controller 160 may subsequently send another command (not shown in FIG. 1) that causes the first memory die 110 to move the write data 186 to one of the page data latches 122, 126 of the first memory die 110, and that causes the second memory die 130 to generate and store parity data based on the write data 186. For example, if the first memory die 110 moves the write data 186 from the transfer data latch 124 to the first page data latch 122 of the first memory die 110, the second memory die 130 may cause the XOR circuitry 140 to perform an XOR operation using the write data 186 and contents of the first page data latch 142 of the second memory die 130. Results of the XOR operation may be stored at the first page data latch 142 of the second memory die 130. Similarly, if the first memory die 110 moves the write data 186 from the transfer data latch 124 to the second page data latch 126 of the first memory die 110, the second memory die 130 may cause the XOR circuitry 140 to perform an XOR operation using the write data 186 and contents of the second page data latch 146 of the second memory die 130. Results of the XOR operation may be stored at the second page data latch 146 of the second memory die 130. Thus, in this example, the page data latches 142, 146 of the second memory die 130 (e.g., an inactive memory die) store parity data associated with data stored at a non-volatile memory of the first memory die 110 (e.g., an active memory die).

The controller 160 may include an event detector 166, e.g., a circuit or instructions executed by a processor of the controller 160. The event detector 166 may be configured to detect events that may cause the data latches storing the parity data to lose power. For example, if the data storage device 102 is removably coupled to the access device 170, the data storage device 102 may receive operational power from the access device 170. In this circumstance, the event detector 166 may detect when the data storage device 102 is decoupled from the access device 170. As another example, when the access device 170 powers down, the access device 170 may notify the data storage device 102 of a power down event, which may be detected by the event detector 166.

Based on the event detector 166 detecting an event that may cause the data latches storing parity data to lose power, the controller 160 may cause the parity data to be stored at a non-volatile memory of the memory 104. For example, if the page data latches 142, 146 of the second memory die 130 are storing parity data associated with data stored at the first memory die 110, the controller 160 may command the second memory die 130 to write the parity data to the second array of memory cells 132. Upon subsequent power up, the parity data may be read from the second array of memory cells 132 back into the page data latches 142, 146 so that the page data latches 142, 146 can continue to aggregate parity data associated with the first memory die 110.

After a programming operation, the memory 104 may send an indication of whether the programming operation was successful. If the memory 104 sends an unsuccessful programing indication 188 (indicating that the programming operation was unsuccessful), the controller 160 may initiate operations to recover data that may have been compromised by the failure of the programming operation. For example, the controller 160 may send one or more commands (e.g., a recover write data command 190) to the memory 104 to cause the memory 104 to perform recovery operations.

The recovery operations may include, for example, programming the write data 186 to a different word line, to a different block, or to a different memory die. Since the write data 186 is stored at one or more of the page data latches 122, 126 of the first memory die 110, the write data 186 can be recovered from the page data latches 122, 126.

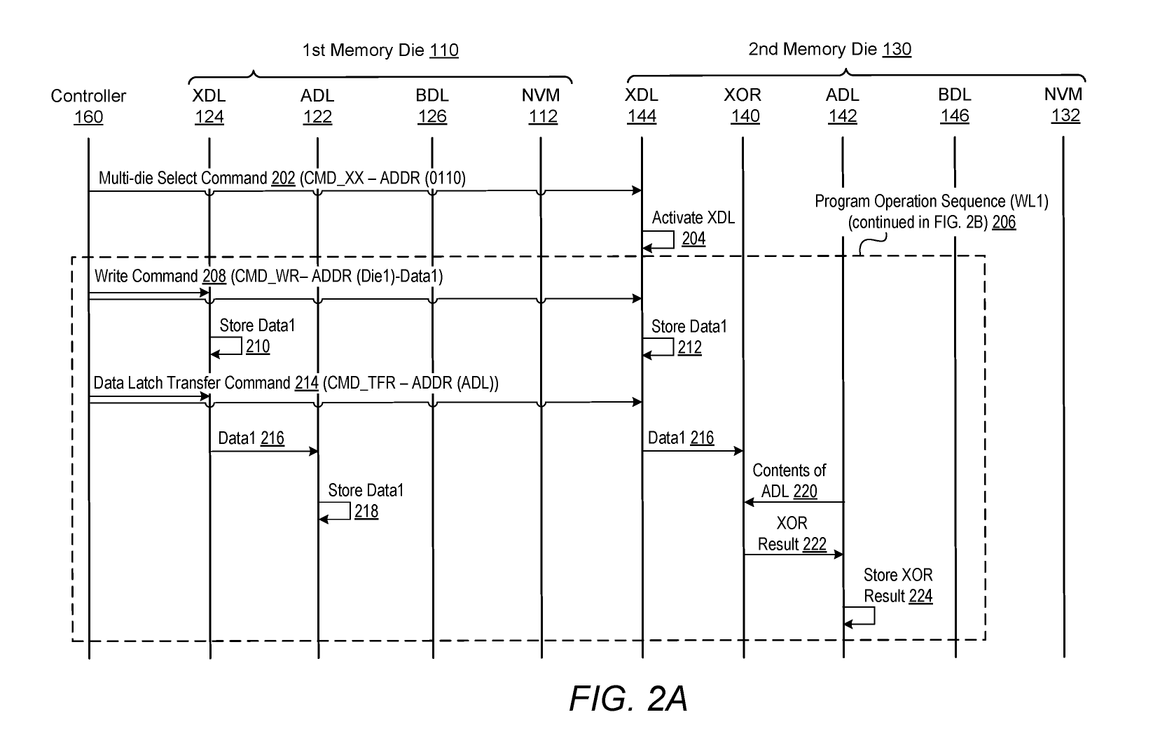

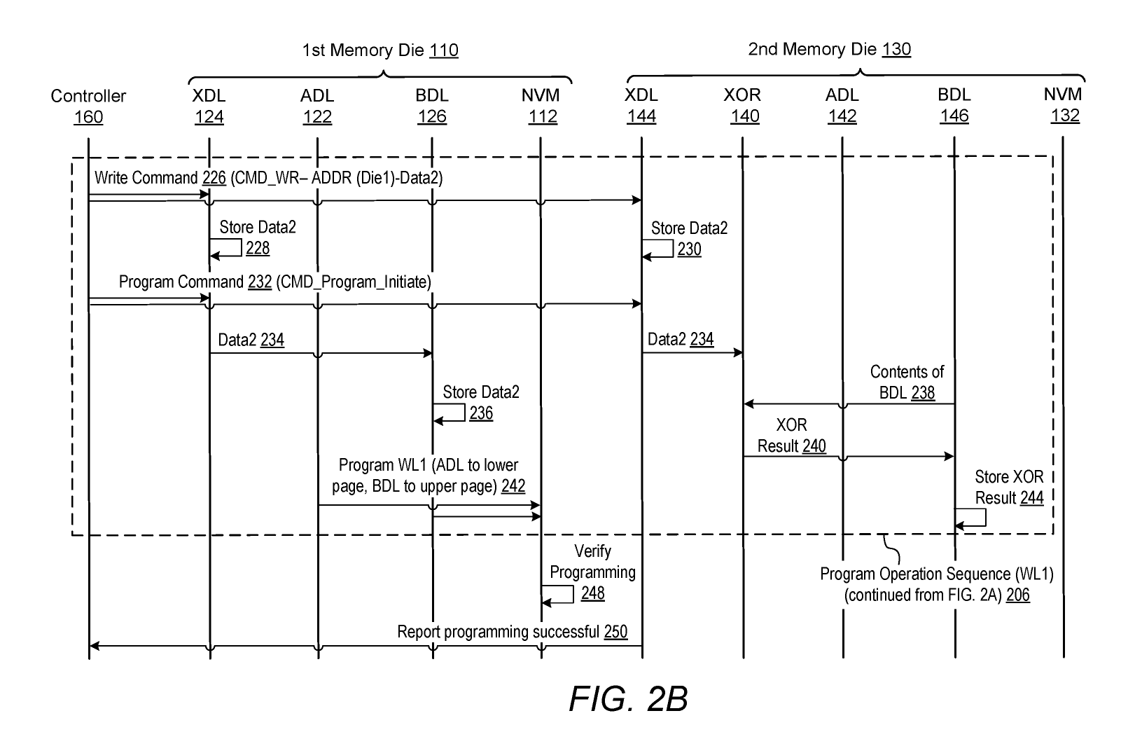

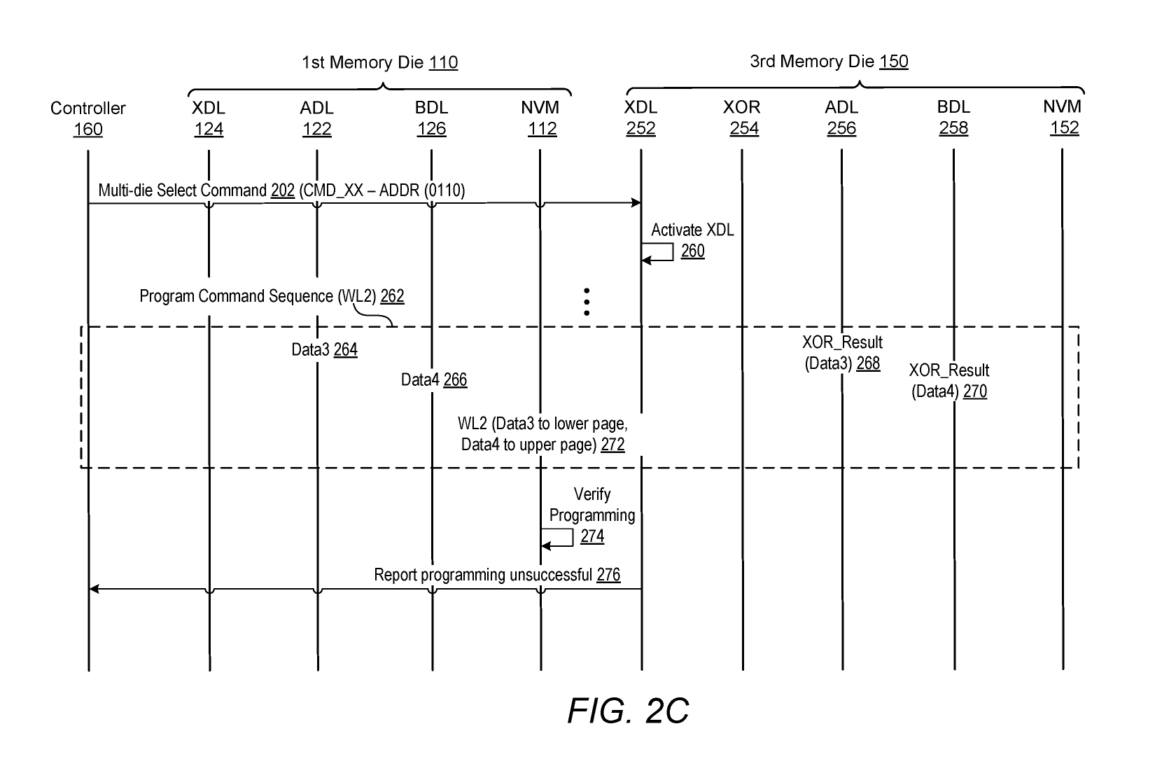

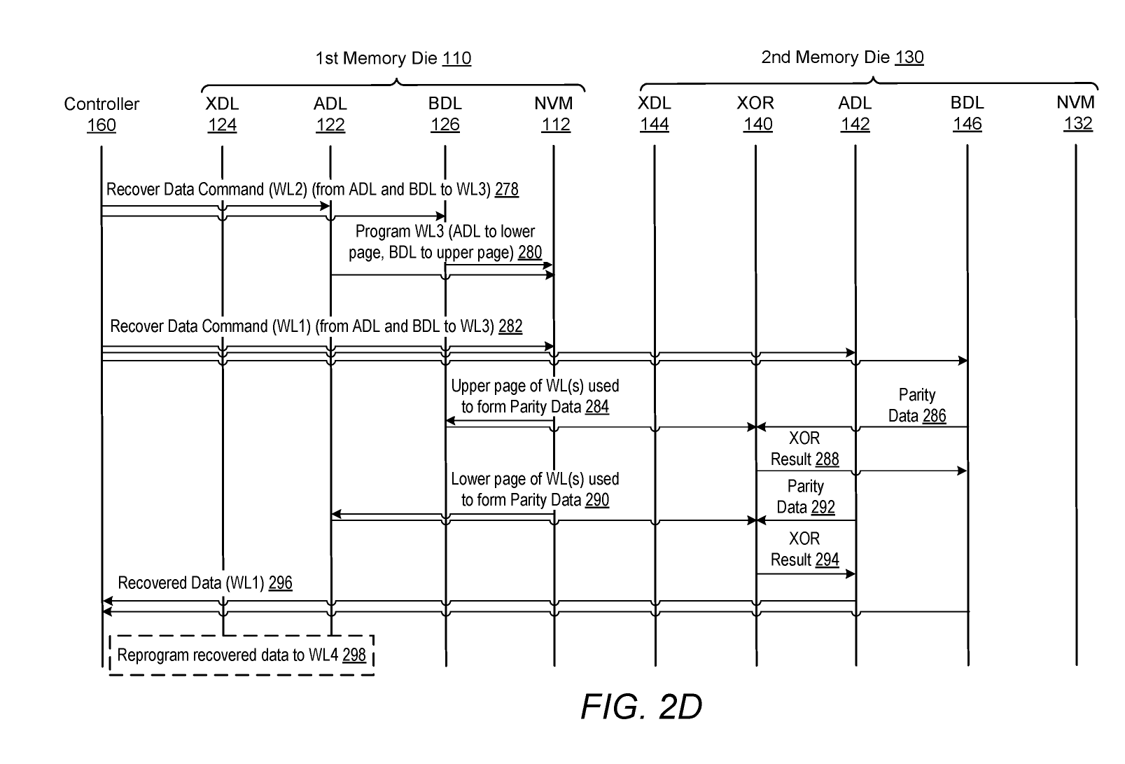

If the unsuccessful programming operation is due to certain types of failures, such as short between word lines, the unsuccessful programming operation may have corrupted data stored at an adjacent word line of the first memory die 110. For example, if the first word line 114 is adjacent to the second word line 116, and the first and second word lines 114, 116 are shorted, then programming the write data 186 to the first word line 114 may corrupt data already stored at the second word line 116. Accordingly, the recovery operations may include using parity data stored at page data latches of another memory die (such as the third memory die 150) to recreate the data that was stored at the second word line 116, as described in more detail with reference to FIG. 2D.

Thus, the data storage device 102 is able to recreate potentially corrupted data (e.g., the data stored at the second word line) using parity data. Since the parity data is stored at data latches of other dies (that are designated as inactive dies), the controller 160 does not need to store the parity data. Thus, a volatile memory of the controller 160 can be reduced.

FIGS. 2A, 2B, 2C and 2D illustrate various aspects of operation the system 100. In particular, FIGS. 2A and 2B show a ladder diagram illustrating operations to program a first word line of the first memory die 110 of the data storage device of FIG. 1. FIGS. 2A and 2B show the controller 160, the first memory die 110 and the second memory die 130. In FIGS. 2A and 2B, the transfer data latch 124 is labeled with the abbreviated legend “XDL” 124, the first page data latch 122 is labeled with the abbreviated legend “ADL” 122, the second page data latch 126 is labeled with the abbreviated legend “BDL” 126, and the first array of memory cells 112 is labeled with the abbreviated legend “NVM” 112. Similarly, in FIGS. 2A and 2B, the XOR circuitry 140 is labeled with the abbreviated legend “XOR” 140, the transfer data latch 144 is labeled with the abbreviated legend “XDL” 144, the first page data latch 142 is labeled with the abbreviated legend “ADL” 142, the second page data latch 146 is labeled with the abbreviated legend “BDL” 126, and the second array of memory cells 132 is labeled with the abbreviated legend “NVM” 132. Although FIGS. 2A-2D illustrate a specific sequence of commands, in other implementations, more commands, fewer commands, different commands, or a different sequence of commands may be used.

In FIGS. 2A-2D, the first memory die 110, the second memory die 130, and the third memory die 150 are configured to operate in a multi-level cell (MLC) configuration, with each memory cell programmable to a state that indicates a bit value of an upper page and a bit value of a lower page (e.g. a two-level cell configuration). In other implementations, the memory dies 110, 130, 150 may be configured to operate in an MLC configuration that includes more than two bits per cell, in which case the number of page data latch of each memory die 110, 130, 150 may correspond to the number of bits per cell. For example, FIG. 3 illustrates an example with three bits per cell and three page data latches per memory die.

In FIG. 2A, the controller 160 sends a multi-die select command, at 202, via the bus 106 to the memory 104. The multi-die select command may correspond to the multi-die select command 182 of FIG. 1. In the example illustrated in FIG. 2A, the multi-die select command includes a command identifier “CMD_XX” and an address field “ADDR(0110)”. The address field includes information identifying which die or dies of the memory 104 are to be selected. For example, in the example illustrated in FIG. 2A, the address field includes a bit map, where each bit corresponds to one die of the memory 104. Thus, in the example of FIG. 2A, the memory 104 includes four memory dies, and the address field indicates that the second and third memory dies are to be selected. The transfer data latch 144 of the second memory die 130 is activated, at 204, based on the multi-select command.

After the controller 160 sends the multi-die select command, the controller 160 may begin a program operation sequence 206. In FIG. 2A, the program operation sequence 206 includes a sequence of operations to program data to the first word line (WL1) 114 of the first memory die 110. At 208, the controller 160 sends a first write command to the first memory die 110. In FIG. 2A, the first write command is shown as received by the transfer data latch 124 of the first memory die 110; however, this is merely for illustration. Rather than being received by the transfer data latch 124, the first write command may be received by another component of the first memory die 110. The first write command of FIG. 2A may include, correspond to, or be included within the write command 184 of FIG. 1. The first write command includes a command identifier “CMD_WR,” an address field “ADDR(Die1),” and first data (“Data1”). The first data may include, correspond to, or be included within the write data 186 of FIG. 1. For example, the first data may include an ECC codeword generated by the ECC engine 162 based on the data 172 of FIG. 1. The address field may include information identifying the first memory die 110 as well as a physical location within the first memory die, such as a physical location corresponding to the first word line 114.

The transfer data latch 124 of the first memory die 110 may store the first data responsive to the first write command, at 210. Additionally, since the transfer data latch 144 of the second memory die 130 was activated by the multi-die select command, the transfer data latch 144 may store the first data responsive to the first write command, at 212. Thus, the first data may be sent to the first memory die 110 and to the second memory die 130 in parallel (e.g., simultaneously or concurrently). Accordingly, no additional time (e.g., a “time penalty”) is used to provide the first data to the second memory die 130 to store parity data associated with the first data.

After sending the first write command, the controller 160 may send a data latch transfer command, at 214. The data latch transfer command may include a command identifier “CMD_TFR” and an address field “ADDR(ADL) specifying a data latch to which the first data is to be transferred. Based on the data latch transfer command, the first memory die 110 may move the first data from the transfer data latch 124 to the first page data latch (ADL) 122, at 216, and the first page data latch 122 may store the first data, at 218. In the particular example illustrated in FIGS. 2A-2D, the first page data latch 122 is a lower page data latch. To illustrate, the first page data latch 122 may store data that is to be written to the lower page of a particular word line during a write operation, and may store data read from the lower page of the particular word line during a read operation.

Also based on the data latch transfer command, the second memory die 130 may provide the first data to the XOR circuitry 140, at 216. In some implementations, the second memory die 130 may store parity data associated with odd-numbered word lines (e.g., the first word line) and the third memory die 150 may store parity data associated with even-numbers word lines (e.g., the second word line, as described with reference to FIG. 2C). If the first word line is not the first odd-numbered word line of the NVM 112 for which parity data is generated, the first page data latch 142 may already include parity data (e.g., aggregate XOR results for all of the odd-numbered word lines of the NVM 112 to which data was previously programmed). Thus, the contents of the first page data latch 142 may be provided to the XOR circuitry 140, at 220, to generate an XOR result (e.g., parity data) based on the first data.

The XOR circuitry 140 performs a bitwise XOR operation based on the first data and the contents of the first page data latch 142 to generate the XOR result (e.g., parity data) and provides the XOR result to the first page data latch 142, at 222. The first page data latch 142 stores the XOR result, at 224. Thus, based on the first write command and the data latch transfer command, the first page data latch 122 of the first memory die 110 stores first data to be written to a lower page of the first word line, and the first page data latch 142 of the second memory die 130 generates and stores parity data associated with the first data.

The program operation sequence 206 for the first word line continues in FIG. 2B. In FIG. 2B, at 226, the controller 160 sends a second write command to the first memory die 110. The second write command of FIG. 2B may include, correspond to, or be included within the write command 184 of FIG. 1. The second write command includes a command identifier “CMD_WR,” an address field “ADDR(Die1),” and second data (“Data2”). The second data may include, correspond to, or be included within the write data 186 of FIG. 1. For example, the second data may include an ECC codeword generated by the ECC engine 162 based on the data 172 of FIG. 1. The address field may include information identifying the first memory die 110 as well as a physical location within the first memory die, such as a physical location corresponding to the first word line 114.

The transfer data latch 124 of the first memory die 110 may store the second data responsive to the second write command, at 228. Additionally, since the transfer data latch 144 of the second memory die 130 was activated by the multi-die select command, the transfer data latch 144 may also store the second data responsive to the second write command, at 230.

After sending the second write command, the controller 160 may send a program command, at 232. The program command may include a command identifier “CMD_Program_Intiate”. Based on the program command, the first memory die 110 may move the second data from the transfer data latch 124 to the second page data latch (BDL) 126, at 234, and the second page data latch 126 may store the second data, at 236. The first memory die 110 may then program the first word line, at 242. In the particular example illustrated in FIGS. 2A-2D, the second page data latch 126 is an upper page data latch. To illustrate, the second page data latch 126 may store data that is to be written to the upper page of a particular word line during a write operation, and may store data read from the upper page of the particular word line during a read operation.

Also based on the program command, the second memory die 130 may provide the second data and contents of the second page data latch (BDL) 146 to the XOR circuitry 140, at 234 and 238. As explained above, the contents of the second page data latch 146 may include parity data (e.g., an aggregate XOR result) based on even-numbered word lines of the NVM 112 to which data has been programmed. The XOR circuitry 140 performs a bitwise XOR operation based on the second data and the contents of the second page data latch 146 to generate an XOR result (e.g., parity data) and provides the XOR result to the second page data latch 146, at 240. The second page data latch 146 stores the XOR result, at 244. Thus, based on the program command, the first memory die 110 programs the first word line to store the first data at a lower page and to store the second data at an upper page. Additionally, based on the second write command and the program command, the second memory die 130 generates and stores parity data associated with the second data.

After programing the first word line, the first memory die 110 may perform operations, at 248, to verify the programming of the first word line. For example, the first memory die 110 may sense the first word line and compare values determined based on sensing the first word line to expected values based on the contents of the first page data latch 122 (e.g., the first data) and contents of the second page data latch 126 (e.g., the second data). In the example illustrated in FIG. 2B, the first memory die 110 determines that the programming was successful and reports the programming successful, at 250, by sending an indication of success programming to the controller 160.

FIG. 2C is a ladder diagram illustrating operations to program a second word line of the first memory die 110 of the data storage device of FIG. 1. The operations to program the second word line are similar to the operation program the first word line, accordingly, a simplified version of the operations is illustrated in FIG. 2C. FIG. 2C shows that when the controller 160 sends the multi-die select command, at 202, the third memory die 150 also receives the multi-die select command and, at 260, activates a transfer data latch 252 of the third memory die 150. In a particular implementation, only one of the transfer data latch 144 of the second memory die 130 or the transfer data latch 252 of the third memory die 150 is activated at a particular time. To illustrate, the second memory die 130 may be designated to store parity data associated with odd-numbered word lines, and the third memory die 150 may be designated to store parity data associated with even-numbered word lines. In this example, the transfer data latch 144 of the second memory die 130 may be activated when the address identified in a write command corresponds to an odd-numbered word line, and the transfer data latch 252 of the third memory die 150 may be activated when the address identified in a write command corresponds to an even-numbered word line. In another example, only the transfer data latch 144 of the second memory die 150 may be activated responsive to the multi-die select command of FIG. 2A. In this example, the controller 160 may send a separate multi-die select command to the third memory die 150 before beginning programming of an even-numbered word line.

In FIG. 2C, a second program operation sequence 262 to program a second word line is illustrated in a simplified manner. Following steps similar to those described for FIGS. 2A and 2B, the second program operation sequence 262 results in third data 264 being stored at the first page data latch 122 of the first memory die 110 and fourth data 266 being stored at the second page data latch 126 of the first memory die 110. Additionally, parity data (e.g., an XOR result 268 generated by the XOR circuitry 254) associated with the third data 264 is stored at a first page data latch 256 of the third memory die 150, and parity data (e.g., an XOR result 270) associated with the fourth data 266 is stored at a second page data latch 258 of the third memory die 150. After the third data 264 is stored at the first page data latch 122 and the fourth data 266 is stored at the second page data latch 126, the second word line is programmed, at 272, based on the third data and the fourth data. For example, the second word line may be programmed such that the third data corresponds to a lower page of the second word line and the fourth data corresponds to an upper page of the second word line.

After programing the second word line, the first memory die 110 may perform operations to verify the programming of the second word line, at 274. In the example illustrated in FIG. 2C, the first memory die 110 determines that the programming was unsuccessful and reports the programming unsuccessful, at 276, by sending an indication of unsuccessful programming to the controller 160.

Based on the indication of unsuccessful programming, the controller 160 may perform operations to recover data that may be compromised. For example, the third data and the fourth data may be compromised (in the NVM 112) since the programming of the second word line was unsuccessful. In addition, if the first word line is adjacent to the second word line in the NVM 112, the first and second data may also be compromised. For example, if the unsuccessful programing was due to a defect that affects the first word line and the second word line, such as a short between the word lines, the unsuccessful programming of the second word line may have corrupted the first word line. Accordingly, to reduce the risk of data loss, based on the unsuccessful programming indication for the second word line, the controller 160 may initiate operations to recover the first data, the second data, the third data, and the fourth data. In some implementations, the recovered data may be programmed to a different location, and the first and second word lines may be marked unused. For example, a block of memory that includes the first and second word lines may be marked unused, and all of the data in that block (including the recovered data) may be moved to a different block of memory (e.g., a spare block).

FIG. 2D is a ladder diagram illustrating operations to recover data of the first word line and the second word line following unsuccessful programming of the second word line of the first memory die 110 of the data storage device of FIG. 1. In FIG. 2D, the controller 160 sends a recover data command associated with the second word line, at 278. The recover data command may include or correspond to a special purpose command (e.g., a command specifically for recovering data). Alternatively, the recover data command may include or correspond to one or more commands that are used during a program or read sequence. Data that was to be programmed to the second word line (e.g., the third data and the fourth data) is stored in the first page data latch 122 and the second page data latch 126, respectively. Accordingly, the recover data command may include a write command, a program command, or another command that causes the first memory die 110 to program the contents of the first page data latch 122 (e.g., the third data) and the contents of the second page data latch 126 (e.g., the fourth data) to a third word line (e.g., at another block of the NVM 112). Based on the recover data command, the first memory die 110 may program the third data and the fourth data to the third word line, at 280.

As explained above, the page data latches 142, 146 of the second memory die 130 store aggregate parity data associated with the odd-numbered word lines, including the first word line. The controller 160 may send a recover data command, at 282, to retrieve the aggregate parity data so that the first data and the second data can be regenerated based on the aggregate parity data. In FIG. 2D, operations that may be used to recover the first and second data are illustrated as a sequence of actions. The sequence of actions is intended to generally illustrate the operations and is not intended to be limiting. To illustrate, in the example of FIG. 2D, the XOR circuitry 140 of the second memory die 130 is used to regenerate the first data and the second data. However, in other implementations, the controller 160 may regenerate the first and second data.

Based on the recover data command, data from upper pages of odd-numbered word lines of the NVM 112 may be provided to the XOR circuitry 140, at 284. Additionally, the parity data stored in the second page data latch 146 may be provided to the XOR circuitry 140, at 286. The XOR circuitry 140 may perform a bitwise XOR operation based on the data from upper pages of odd-numbered word lines of the NVM 112 and the parity data stored in the second page data latch 146 to generate an XOR result, at 288. The XOR result corresponds to the second data regenerated based on the parity data and all of the data used to generate the parity data (e.g., the data from upper pages of odd-numbered word lines of the NVM 112) except for the second data. Stated another way, the parity data stored in the second page data latch 146 is an aggregate result of a series of bitwise XOR operations based on the second data and the data stored in upper pages of the odd-numbered word lines of the NVM 112, as described above with reference to FIG. 2B. The XOR result generated by performing a bitwise XOR operation based on the parity data and data stored in upper pages of odd-numbered word lines except for the first word line of the NVM 112 corresponds to the second data.

Similarly, based on the recover data command, data from lower pages of odd-numbered word lines of the NVM 112 may be provided to the XOR circuitry 140, at 290. Additionally, the parity data stored in the first page data latch 142 may be provided to the XOR circuitry 140, at 292. The XOR circuitry 140 may perform a bitwise XOR operation based on the data from lower pages of odd-numbered word lines of the NVM 112 and the parity data stored in the first page data latch 142 to generate an XOR result, at 294. The XOR result corresponds to the first data regenerated based on the parity data and all of the data used to generate the parity data (e.g., the data from lower pages of odd-numbered word lines of the NVM 112) except for the first data.

In the example illustrated in FIG. 2D, the recovered data of the first word line (e.g., the first data and the second data) may be provided to the controller 160, at 296. The controller 160 may reprogram the recovered data of the first word line to a different word line (e.g., a fourth word line), at 298. Thus, the controller 160 is able to recreate potentially corrupted data (e.g., the data stored at the first word line) using parity data stored at data latches of an inactive die (e.g., the second memory die 130 in the example of FIGS. 2A-2D). Since the controller 160 does not need to store the parity data, a volatile memory of the controller 160 can be reduced relative to a controller that stores such parity data.

FIG. 3 is a block diagram illustrating a particular example of mapping of word lines of a memory die to corresponding parity data stored in data latches of other memory dies of the data storage device of FIG. 1. FIG. 3 shows the first memory die 110, the second memory die 130 and the third memory die 150 of FIG. 1. In the example illustrated in FIG. 3, the first memory die 110 is configured to operate in a triple-level cell (TLC) configuration in which each programmed memory cell has a state that indicates a bit value of an upper page, a bit value of a middle page, and a bit value of a lower page. Thus, each word line of the first memory die 110 is shown having three pages of data. Additionally, the second memory die 130 includes at least three page data latches, including the first page data latch (ADL) 142, the second page data latch (BDL) 146, and a third page data latch (CDL) 310. The third memory die 150 includes at least three page data latches, including a first page data latch (ADL) 312, a second page data latch (BDL) 314, and a third page data latch (CDL) 316. Each of the memory dies 110, 130, 150 may also include other components that are not shown in FIG. 3. For example, the second memory die 130 and the third memory die 150 may include one or more transfer data latches, XOR circuitry, and non-volatile memory, as described with reference to FIGS. 1 and 2A-2D. Further, the first memory die 110 may include data latches, such as one or more transfer data latches, XOR circuitry, and one or more page data latches.

In the mapping scheme used in FIG. 3, parity data associated with odd-numbered word lines 114, 302, 306 of the first memory die 110 are stored at the page data latches 142, 146, 310 of the second memory die 130, and parity data associated with even-numbered word lines 116, 304, 308 of the first memory die 110 are stored at the page data latches 312, 314, 316 of the third memory die 150. For example, accumulated upper page parity data 380 is stored in the first page data latch 142 of the second memory die 130. The accumulated upper page parity data 380 corresponds to results of bitwise XOR operations based on upper page data 320, 332, 344 of odd-numbered word lines 114, 302, 306 of the first memory die 110. Similarly, the second page data latch 146 of the second memory die 130 stores accumulated middle page parity data 382 corresponding to results of bitwise XOR operations based on middle page data 322, 334, 346 of the odd-numbered word lines 114, 302, 306 of the first memory die 110. Additionally, the third page data latch 310 of the second memory die 130 stores accumulated lower page parity data 384 corresponding to results of bitwise XOR operations based on lower page data 324, 336, 348 of the odd-numbered word lines 114, 302, 306 of the first memory die 110.

Continuing the example above, the first page data latch 312 of the third memory die 150 stores accumulated upper page parity data 386 corresponding to results of bitwise XOR operations based on upper page data 326, 338, 350 of the even-numbered word lines 116, 304, 308 of the first memory die 110. Similarly, the second page data latch 314 of the third memory die 150 stores accumulated middle page parity data 388 corresponding to results of bitwise XOR operations based on middle page data 328, 340, 352 of the even-numbered word lines 116, 304, 308 of the first memory die 110. Additionally, the third page data latch 316 of the third memory die 150 stores accumulated lower page parity data 390 corresponding to results of bitwise XOR operations based on lower page data 330, 342, 354 of the even-numbered word lines 116, 304, 308 of the first memory die 110.

Thus, one or more inactive memory dies (e.g., the second memory die 130 and the third memory die 150 in the example of FIG. 3) can be used to store parity data associated with one or more active dies (e.g., the first memory die 110 in FIG. 3). Although only one active die is shown in FIG. 3, a data storage device, such as the data storage device 102 of FIG. 1, may include more than one active die at a time. To illustrate, in some implementations, at any particular time, half of the memory dies of a data storage device may be active, and the other half of the memory dies may be inactive. Storing parity data associated with the active dies at inactive memory dies enables recovery of data that is potentially corrupted (e.g., due to a program operation) without using a volatile memory of the controller to store the parity data. To illustrated, if the data 320, 322, 324 stored in the first word line 114 of the first memory die 110 is potentially corrupted, the accumulated parity data 380, 382, 384 can be used with the data stored at other odd-numbered word lines 302, 306 to recreate the data 320, 322, 324.

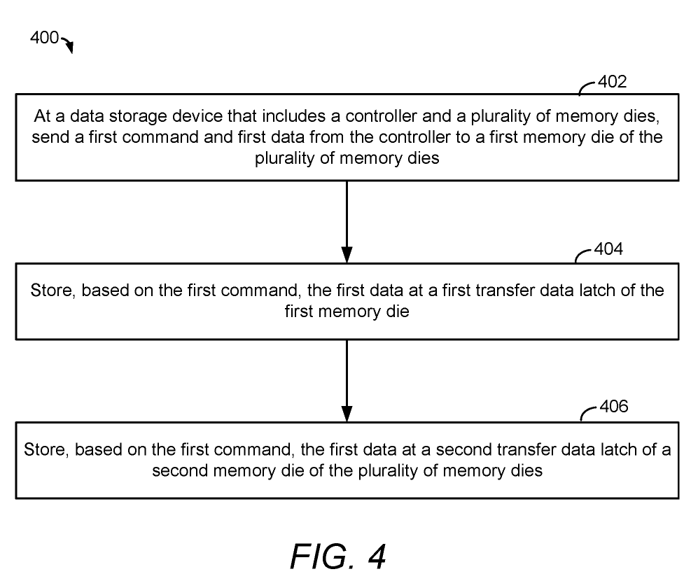

FIG. 4 illustrates a flow diagram of an illustrative method 400 of operation of the data storage device of FIG. 1. For example, the method 400 may be performed at a data storage device (e.g., the data storage device 102) that includes a plurality of memory dies (e.g., the memory dies 110, 130, 150, 156).

The method 400 includes, at 402, sending a first command and first data from the controller to a first memory die of the plurality of memory dies. The first memory die may correspond to the first memory die 110 of FIGS. 1 and 2A-2D. In an illustrative example, the first command corresponds to the write command 184 of FIG. 1, and the first data of the method 400 corresponds to the write data 186. In another illustrative example, the first command corresponds to the write command sent at 208 of FIG. 2A, which includes first data (Data1) corresponding to the first data of the method 400. In yet another illustrative example, the first command corresponds to the write command sent at 226 of FIG. 2B, which includes second data (Data2) corresponding to the first data of the method 400.

The method 400 includes, at 404, storing, based on the first command, the first data at a first transfer data latch of the first memory die. The first transfer data latch may correspond to the transfer data latch 124 of FIGS. 1 and 2A-2D. In an illustrative example, the first data of the method 400 corresponds to the write data 186 of FIG. 1, which may be stored at the transfer data latch 124 based on the write command 184 of FIG. 1. In another illustrative example, the first data corresponds to the first data (Data1) of the write command sent at 208 of FIG. 2A. In this illustrative example, the first data (Data1) is stored at the transfer data latch 124 of the first memory die 110 based on the write command sent at 208. In another illustrative example, the first data corresponds to the second data (Data2) of the write command sent at 226 of FIG. 2B. In this illustrative example, the second data (Data2) is stored at the transfer data latch 124 of the first memory die 110 based on the write command sent at 226.

The method 400 includes, at 406, storing, based on the first command, the first data at a second transfer data latch of a second memory die of the plurality of memory dies. The second transfer data latch may correspond to the transfer data latch 144 of the second memory die 130 of FIGS. 1 and 2A-2D. In an illustrative example, the first data of the method 400 corresponds to the write data 186 of FIG. 1, which may be stored at the transfer data latch 144 based on the write command 184 of FIG. 1 (and based on the multi-die select command 182). In another illustrative example, the first data corresponds to the first data (Data1) of the write command sent at 208 of FIG. 2A. In this illustrative example, the first data (Data1) is stored at the transfer data latch 144 of the second memory die 130 based on the write command sent at 208 (and based on the multi-die select command sent at 202). In another illustrative example, the first data corresponds to the second data (Data2) of the write command sent at 226 of FIG. 2B. In this illustrative example, the second data (Data2) is stored at the transfer data latch 144 of the second memory die 130 based on the write command sent at 226 (and based on the multi-die select command sent at 202).

The method 400 may include, before sending the first command, sending a second command from the controller to the second memory die and activating the second transfer data latch based on the second command. For example, the second command may include or correspond to a multi-die select command. To illustrate, the multi-die select command 182 of FIG. 1 may be sent before the write command 184 is sent. In this example, the transfer data latch 144 of the second memory die 130 may be activated based on the multi-die select command 182. In this context, activating the transfer data latch 144 of the second memory die 130 enables the transfer data latch 144 to store data that is received via the bus 106 even though the data is associated with a write command that is not addressed to the second memory die 130.

The method 400 may include storing the first data at a first page data latch of the first memory die responsive to a data latch transfer command from the controller. For example, in response to the data latch transfer command sent at 214 of FIG. 2A, the first data may be moved from the transfer data latch 124 to the first page data latch 122. The method 400 may also include performing, responsive to the data latch transfer command, a bitwise exclusive-OR (XOR) operation based on the first data and contents of a particular page data latch of the second memory die and storing a result of the bitwise XOR operation at the particular page data latch. For example, in response to the data latch transfer command sent at 214 of FIG. 2A, the XOR circuitry 140 may perform a bitwise XOR operation based on the first data (from the transfer data latch 144) and the contents of the first page data latch 142 of the second memory die 130. In this example, the result of the XOR operation may be stored at the first page data latch 142.

The method 400 may include, after storing the first data at the first page data latch of the first memory die, sending a second command and a second data from the controller to the first memory die and, based on the second command, storing the second data at the first transfer data latch of the first memory die. In an illustrative example, the second command corresponds to the write command sent at 226 of FIG. 2B. In this illustrative example, the second data (Data2) is stored at the transfer data latch 124 of the first memory die 110 based on the write command sent at 226. The method 400 may also include, storing the second data at the transfer data latch of the second memory die based on the second command. In an illustrative example, the second data (Data2) is stored at the transfer data latch 144 of the second memory die 130 based on the write command sent at 226 (and based on the multi-die select command sent at 202).

The method 400 may include detecting an event and storing the result of the bitwise XOR operation to a non-volatile memory of the second memory die based on detecting the event. For example, the event detector 166 may detect an event indicating that power to the page data storage latches may be lost. To illustrate, the event may be a power down event detected by the event detector 166 based on a signal from the access device 170 or based on detecting that the data storage device 102 has disconnected from the access device 170. Based on the event detector 166 detecting the event, the controller 160 may cause parity data stored in page data latches of the memory 104 to be programmed to non-volatile memory of the memory 104. To illustrate, when the page data latches 142, 146 of the second memory die 130 store parity data associated with the first memory die 110, the controller 160 may cause the contents of the page data latches 142, 146 to be programmed to the second array of memory cells 132 in response to detecting the event.

The method 400 may include, after storing the first data to a first word line of the first memory die, determining that programming of a second word line of the first memory die was not successful and recovering the first data based on the result of the bitwise XOR operation. For example, as described with reference to FIG. 2D, the parity data stored at the page data latches of the second memory die 130 can be used (along with data stored in other word lines of the first memory die 110) to regenerate the first data.

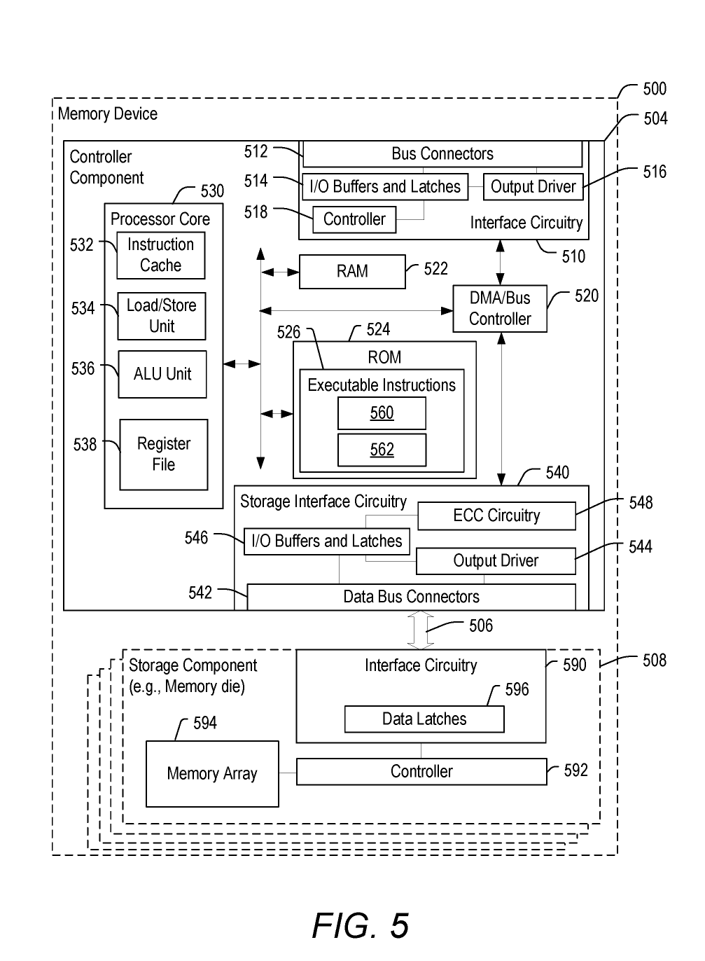

Referring to FIG. 5, an illustrative example of a memory device is depicted and generally designated 500. The memory device 500 includes a controller component 504 coupled to one or more storage components (e.g., memory dies), such as a representative storage component 508, via a bus 506. The representative storage component 508 includes interface circuitry 590 to communicate via the bus 506. The interface circuitry 590 may include data latches 596. The data latches 596 may correspond to the data latches 122, 124, 126 (or other data latches) of FIGS. 1 and 2A-2D. The storage component 508 also includes a controller 592 that is coupled to the interface circuitry 590 and that is also coupled to a memory, such as a memory array 594. The memory array 594 may include one or more types of storage media, such as a NAND flash array or a ReRAM array. The memory array 594 may have a 3D memory configuration. Alternatively, the memory array 594 may have another configuration, such as a 2D memory configuration. In a particular implementation, the memory device 500 may correspond to the data storage device 102 of FIG. 1.

In a particular implementation, the controller component 504 includes interface circuitry 510 coupled to a direct memory access (DMA)/bus controller 520. The controller component 504 also includes storage interface circuitry 540 that is coupled to the DMA/bus controller 520. A processor core 530, a random access memory (RAM) 522 and a read-only memory (ROM) 524 are coupled to the DMA/bus controller 520 via an internal bus.

In a particular implementation, the interface circuitry 510 includes bus connectors 512 coupled to input/output (I/O) buffers and latches 514. The bus connectors 512 are further coupled to output driver circuitry 516. The interface circuitry 510 also includes a controller 518. In a particular implementation, the interface circuitry 510 operates in accordance with a universal serial bus (USB) protocol. For example, the controller 518 may be programmed to receive USB protocol instructions and data from an access device (not shown) via the bus connectors 512 that are coupled to a universal serial bus. The controller 518 may include a hardware processor that executes instructions stored at an internal memory, such as a read-only memory (not shown) to enable receipt and acknowledgment of USB instructions and data. Alternatively, or in addition, the interface circuitry 510 may be configured to support other communication protocols, such as a Secure Digital (SD) protocol, a small computer system interface (SCSI), a parallel interface, a serial interface, such as a serial peripheral interface (SPI), a Compact Flash (CF) protocol, one or more other protocols, or any combination thereof.

In a particular implementation, the processor core 530 includes an instruction cache 532, a load/store unit 534, an arithmetic logic unit (ALU) unit 536, and a register file 538. The processor core 530 may include, or may function substantially similarly to, an ARM core, as an illustrative, non-limiting example. For example, the processor core 530 may support a reduced instruction set computer (RISC) micro-architecture. The processor core 530 may be configured to retrieve data and executable instructions 526 via the load/store unit 534 from the ROM 524. The executable instructions 526 may be executable by the processor core 530 to perform one or more operations described herein.

Alternatively, or in addition, at least some of the executable instructions 526 may not be stored at the ROM 524 and may be stored at the memory array 594. The executable instructions 526 may be retrieved from the memory array 594 and stored at the RAM 522. The processor core 530 may be configured to retrieve the executable instructions 526 from the RAM 522 for execution.

The executable instructions 526 may be retrieved by the load/store unit 534 and stored to the instruction cache 532. The ALU unit 536 may include dedicated circuitry to perform arithmetic and logic operations, such as addition and subtraction, AND, NOT, OR, exclusive-OR (XOR), other arithmetic or logic operations, or any combination thereof. It should be appreciated that the storage component 508 may include logic gates and/or an ALU unit (not shown) configured to perform arithmetic logic operations.

In a particular implementation, the executable instructions 526 may include instructions 560 to generate and send a multi-die select command, such as the multi-die select command 182 of FIG. 1 or the multi-die select command sent at 202 of FIG. 2A. In this implementation, the instructions 560 may be executable by the processor core 530 to generate and send a multi-die select command via the bus 506 to one or more of the storage components 508 to cause the one or more storage components 508 addressed by the multi-die select command to receive and store write data despite not being addressed in a write command associated with the write data. Thus, the instructions 560 may enable the one or more storage components 508 addressed by the multi-die select command to generate and store parity data associated with the write data.

In a particular implementation, the executable instructions 526 may include instructions 562 to recover data in response to an unsuccessful programming indication, such as the unsuccessful programming indication 188 of FIG. 1 or the report that programming was unsuccessful sent at 276 of FIG. 2C. In this implementation, the instructions 562 may be executable by the processor core 530, in response to the unsuccessful programming indication, to generate and send one or more commands to one or more of the storage components 508 to cause the one or more storage components 508 to recover data that may have been corrupted by the unsuccessful programming attempt, as described with reference to FIG. 2D.

The register file 538 may include multiple memory cells that may provide high speed access to the processor core 530 of data to be used for execution of instructions. One or more memory cells at the register file 538 may be dedicated to store a status indicator. Additional data values, such as values to indicate memory type, memory write status, and write protect status, may also be set during execution of the executable instructions 526 at the processor core 530.

The storage interface circuitry 540 may include data bus connectors 542, an output driver 544, input/output buffers and latches 546, and ECC circuitry 548. The data bus connectors 542 may include electrical connectors to enable electrical signal propagation via the bus 506. The I/O buffers and latches 546 may be configured to store data that is received via the DMA/bus controller 520 to be transmitted via the bus 506 using electrical signals at the data bus connectors 542 that are generated by the output driver 544. In addition, or alternatively, the I/O buffers and latches 546 may store data values represented by electrical signals received at the data bus connectors 542 via the bus 506, such as signals generated by the interface circuitry 590 of the storage component 508.

The ECC circuitry 548 may correspond to the ECC engine 162 of FIG. 1. The ECC circuitry 548 may include dedicated hardware and circuitry configured to perform operations using data and error correcting code information corresponding to the data that are received as a result of a memory read from the storage component 508, and may perform logical or arithmetic operations to verify that the received data is not detected to have corrupted values. For example, the received data may include additional bits representing an error correcting code, which may be encoded based on values of the data upon storage at the memory array 594. Corruption of one or more bits of the data, or one or more bits of the error correcting code, may be detectable by the ECC circuitry 548. For example, the storage interface circuitry 540 may include a flash memory interface, and the ECC circuitry 548 may be compliant with one or more flash error correcting code protocols.

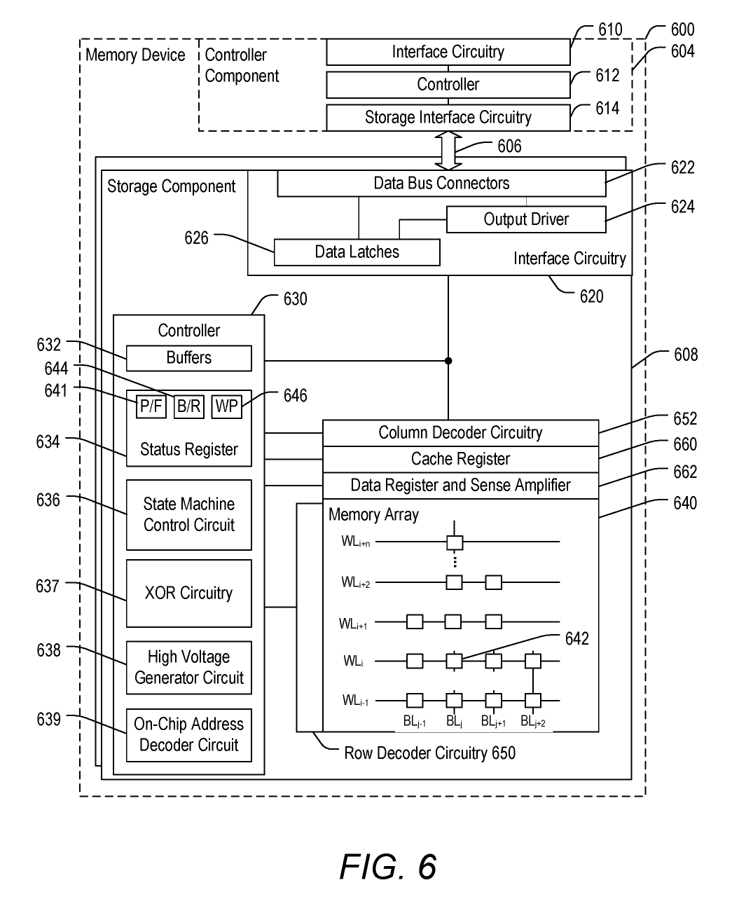

Referring to FIG. 6, an illustrative implementation of a memory device is depicted and generally designated 600. The memory device 600 includes a controller component 604 coupled to a storage component 608. In a particular implementation, the memory device 600 may correspond to the data storage device 102 of FIG. 1. For example, the controller component 604 may correspond to the controller 160 of FIG. 1, and the storage component 608 may correspond to one of the memory dies 110, 130, 150, 156 of FIG. 1. The storage component 608 may have a 3D memory configuration. Alternatively, the storage component 608 may have another configuration, such as a 2D memory configuration.

The controller component 604 may include interface circuitry 610, a controller 612, and storage interface circuitry 614. The controller component 604 may be coupled to the storage component 608 via a data bus 606, such as an 8-bit or 16-bit parallel data bus, as an illustrative, non-limiting example. The controller component 604 may communicate instructions and data with an external host (not shown) via the interface circuitry 610. The controller 612 may be configured to respond to instructions received by the interface circuitry 610 and may also be configured to send and receive data and instructions to the storage component 608 via the storage interface circuitry 614.

In a particular implementation, the storage component 608 includes interface circuitry 620, a controller 630 coupled to the interface circuitry 620, and a memory array 640 accessible to the controller 630. The storage component 608 may include one or more sets of row decoder circuitry, such as row decoder circuitry 650. The storage component may further include column decoder circuitry 652. The row decoder circuitry 650 and the column decoder circuitry 652 may enable access to data stored at one or more particular rows and particular columns of the memory array 640, such as to read a value from or to write a value to a particular memory cell 642 at a bit line BLⱼ and at word line WLᵢ. A cache register 660 and a data register and sense amplifier 662 may further be coupled to the memory array 640 and may be used to cache or to temporarily store data that is to be written to the memory array 640 or data that has been read out of the memory array 640. In a particular implementation, the memory array 640 may include a flash memory or a ReRAM. The memory array 640 may have a 3D memory configuration.

In a particular implementation, the controller 630 includes one or more buffers 632 to store instructions, data, or any combination thereof. The controller 630 may also include one or more status registers 634, a state machine control circuit 636, XOR circuitry 637, a high voltage generator circuit 638, and an on-chip address decoder circuit 639. The XOR circuitry 637 may correspond to the XOR circuitry 120 of FIGS. 1 and 2A-2D and may be configured to generate parity data corresponding to data stored at another storage component, to recreate data that may have been corrupted during an unsuccessful programing attempt, or both.

In a particular implementation, the status register 634 of the controller 630 may include one or more indicators storing values, such as a pass/fail (P/F) value 641, a busy/ready (B/R) value 644, a write protect (WP) value 646, one or more other indicators, or a combination thereof. The status register 634 may be accessible to the state machine control circuit 636.

The state machine control circuit 636 may include dedicated hardware and circuitry to control an operation of the controller 630 in response to one or more received instructions and internal states, such as may be represented at the status register 634. The state machine control circuit 636 may include states such as a read status state, a data write state, a data read state, as illustrative, non-limiting examples.

In a particular implementation, the high voltage generator circuit 638 may be responsive to the state machine control circuit 636 and may be configured to generate a high voltage to program values to, or erase values from, the memory array 640. For example, the memory array 640 may be a flash memory or other memory that may be programmable or erasable via a “high” voltage, such as, for example, five volts (V). Alternatively, the memory array 640 may include a ReRAM. The memory array 640 may have a 3D memory configuration, such as a vertical 3D memory configuration (e.g., a vertical 3D NAND flash memory configuration). The controller 630 may also include the on-chip address decoder circuit 639 that may include hardware and logic circuitry to receive memory address information from the controller component 604 and to decode the memory address information to specific rows and columns to be provided to the row decoder circuitry 650 and the column decoder circuitry 652.

The interface circuitry 620 may include data bus connectors 622, an output driver 624 coupled to the data bus connectors 622, and data latches 626. The data latches 626 may be configured to store or to latch data that is received via the data bus connectors 622, data that is to be written to the data bus 606 via the data bus connectors 622, or parity data associated with another storage component (as described with reference to FIGS. 1-4). For example, the data latches 626 may include or correspond to the data latches 122, 124, 126 of FIG. 1. The data bus connector 622 may include physical electrical connectors that couple the interface circuitry 620 to the data bus 606. The output driver 624 may include dedicated circuitry and electrical connections to enable the interface circuitry 620 to drive electrical signals over the data bus 606. In a particular implementation, the interface circuitry 620 is configured to comply with one or more bus communications protocols or standards.

Although the controller 160 and certain other components described herein are illustrated as block components and described in general terms, such components may include one or more microprocessors, state machines, and/or other circuits configured to enable the data storage device 102 (or one or more components thereof) to perform operations described herein. One or more components described herein may be operationally coupled using one or more nodes, one or more buses (e.g., data buses and/or control buses), one or more other structures, or a combination thereof. One or more components described herein may include one or more physical components, such as hardware controllers, state machines, logic circuits, one or more other structures, or a combination thereof, to enable the data storage device 102 to perform one or more operations described herein. As an illustrative example, the XOR circuitry 120, 140, 254 may include logic gates, such as complementary metal-oxide-semiconductor (CMOS) logic gates. The logic gates may be configured to perform logical operations, such as bitwise XOR operations.

Alternatively or in addition, one or more aspects of the data storage device 102 may be implemented using a microprocessor or microcontroller programmed (e.g., by executing instructions) to perform operations described herein, such as one or more operations of the method 400 of FIG. 4. In a particular implementation, the data storage device 102 includes a processor executing instructions (e.g., firmware) retrieved from the memory 104. Alternatively or in addition, instructions that are executed by the processor may be retrieved from a separate memory location that is not part of the memory 104, such as at a read-only memory (ROM).

To further illustrate, the controller 160 may include a processor that is configured to execute instructions to perform certain operations described herein. The instructions may include general purpose instructions, and the processor may include a general purpose execution unit operable to execute general purpose instructions. As an illustrative example, the processor may execute the instructions to send commands to cause first data to be stored at a first transfer data latch of a first memory die and to cause the first data to be stored at a second transfer data latch of a second memory die. For example, the commands may include the multi-die select command 182 and the write command 184 of FIG. 1.

It should be appreciated that one or more operations described herein as being performed by the controller 160 may be performed at the memory 104. As an illustrative example, “in-memory” ECC operations may be performed at one or more of the memory dies 110, 130, 150, 156 alternatively or in addition to performing ECC operations at the controller 160.

The data storage device 102 may be attached to or embedded within one or more access devices, such as within a housing of a host communication device (e.g., the access device 170). For example, the data storage device 102 may be integrated within an apparatus such as a mobile telephone, a computer (e.g., a laptop, a tablet, or a notebook computer), a music player, a video player, a gaming device or console, an electronic book reader, a personal digital assistant (PDA), a portable navigation device, or other device that uses internal non-volatile memory. However, in other implementations, the data storage device 102 may be implemented in a portable device configured to be selectively coupled to one or more external devices, such as the access device 170.

To further illustrate, the data storage device 102 may be configured to be coupled to the access device 170 as embedded memory, such as in connection with an embedded MultiMedia Card (eMMC®) (trademark of JEDEC Solid State Technology Association, Arlington, Va.) configuration, as an illustrative example. The data storage device 102 may correspond to an eMMC device. As another example, the data storage device 102 may correspond to a memory card, such as a Secure Digital (SD®) card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The data storage device 102 may operate in compliance with a JEDEC industry specification. For example, the data storage device 102 may operate in compliance with a JEDEC eMMC specification, a JEDEC Universal Flash Storage (UFS) specification, one or more other specifications, or a combination thereof.

The memory 104 may include a three-dimensional (3D) memory, a flash memory (e.g., a NAND memory, a NOR memory, a single-level cell (SLC) flash memory, a multi-level cell (MLC) flash memory, a divided bit-line NOR (DINOR) memory, an AND memory, a high capacitive coupling ratio (HiCR) device, an asymmetrical contactless transistor (ACT) device, or another flash memory), an erasable programmable read-only memory (EPROM), an electrically-erasable programmable read-only memory (EEPROM), a read-only memory (ROM), a one-time programmable memory (OTP), a resistive random access memory (ReRAM), or a combination thereof. Alternatively or in addition, the memory 104 may include another type of memory. The memory 104 may include a semiconductor memory device.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some implementations include a resistivity switching storage element, such as an anti-fuse, phase change material, etc., and optionally a steering element, such as a diode, etc. Further by way of non-limiting example, active semiconductor memory elements include EEPROM and flash memory device elements, which in some implementations include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate). As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in they direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Alternatively, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three dimensional exemplary structures described but cover all relevant memory structures within the spirit and scope of the invention as described herein and as understood by one of skill in the art. The illustrations of the implementations described herein are intended to provide a general understanding of the various implementations. Other implementations may be utilized and derived from the disclosure, such that structural and logical substitutions and changes may be made without departing from the scope of the disclosure. This disclosure is intended to cover any and all subsequent adaptations or variations of various implementations. Those of skill in the art will recognize that such modifications are within the scope of the present disclosure.

The above-disclosed subject matter is to be considered illustrative, and not restrictive, and the appended claims are intended to cover all such modifications, enhancements, and other implementations, that fall within the scope of the present disclosure. Thus, to the maximum extent allowed by law, the scope of the present invention is to be determined by the broadest permissible interpretation of the following claims and their equivalents, and shall not be restricted or limited by the foregoing detailed description.

What is claimed is:

1. A data storage device comprising:
a first memory die comprising first memory cells and a first transfer data latch;
a second memory die comprising second memory cells and a second transfer data latch;
a bus coupled to the first memory die and the second memory die; and
a controller coupled to the bus and configured to cause the first transfer data latch and the second transfer data latch to store first data responsive to sending the first data to the first memory die for programming of the first data to a first word line of the first memory cells.

2. The data storage device of claim 1, wherein the first memory die further comprises a first plurality of page data latches, and the first memory die is configured to send the first data from the first transfer data latch to a first page data latch of the first plurality of page data latches responsive to a first data latch transfer command from the controller.

3. The data storage device of claim 2, wherein the second memory die further comprises a second plurality of page data latches, and the second memory die is configured to store parity data associated with the first data at a first page data latch of the second plurality of page data latches responsive to the first data latch transfer command.

4. The data storage device of claim 3, wherein the second memory die is further configured to generate the parity data by performing a bitwise exclusive-OR (XOR) operation based on the first data and contents of the first page data latch of the second plurality of page data latches.

5. The data storage device of claim 2, wherein the controller is further configured to cause the first transfer data latch and the second transfer data latch to store second data responsive to sending the second data to the first memory die for programming of the second data to the first word line and wherein the first memory die is further configured to send the second data from the first transfer data latch to a second page data latch of the first plurality of page data latches responsive to a second data latch transfer command from the controller.

6. The data storage device of claim 5, wherein the second memory die is further configured to store parity data associated with the second data at a second page data latch of a second plurality of page data latches responsive to the second data latch transfer command.

7. The data storage device of claim 2, wherein the first memory die is further configured to program the first word line based on contents of the first plurality of page data latches responsive to a program command from the controller.

8. The data storage device of claim 1, further comprising a third memory die comprising third memory cells and a third transfer data latch, wherein the controller is further configured to cause the first transfer data latch and the third transfer data latch to store second data responsive to sending the second data to the first memory die for programming of the second data to a second word line of the first memory cells.

9. The data storage device of claim 8, wherein the first word line is adjacent to the second word line in the first memory cells.

10. The data storage device of claim 9, wherein the controller is further configured to, based on an indication of unsuccessful programming to the second word line, determine the first data based on parity data stored at the second memory die.

11. A data storage device comprising:
a first memory die of a plurality of memory dies, the first memory die comprising first memory cells;
a second memory die of the plurality of memory dies, the second memory die comprising second memory cells and a plurality of data latches; and
a controller coupled to the first memory die and to the second memory die and configured to cause first data to be stored at the first memory cells and to cause parity data associated with the first data to be generated at the second memory die and stored at the plurality of data latches of the second memory die.

12. The data storage device of claim 11, wherein the second memory die further comprises parity circuitry configured to perform a bitwise exclusive-OR (XOR) operation based on the first data and contents of a particular data latch of the plurality of data latches.

13. The data storage device of claim 11, wherein the controller is configured to designate a first set of memory dies of the plurality of memory dies as active dies and to designate a second set of memory dies of the plurality of memory dies as inactive dies, wherein particular data to be stored in non-volatile memory is stored at an active die and parity data corresponding to the particular data is stored at a data latch of an inactive die.

14. A method comprising:
at a data storage device that includes a controller and a plurality of memory dies, performing:
sending a first command and first data from the controller to a first memory die of the plurality of memory dies;
storing, based on the first command, the first data at a first transfer data latch of the first memory die; and
storing, based on the first command, the first data at a second transfer data latch of a second memory die of the plurality of memory dies.

15. The method of claim 14, further comprising:
before sending the first command, sending a second command from the controller to the second memory die; and
activating the second transfer data latch based on the second command.

16. The method of claim 14, further comprising:
storing, responsive to a data latch transfer command from the controller, the first data at a first page data latch of the first memory die;
performing, responsive to the data latch transfer command, a bitwise exclusive-OR (XOR) operation based on the first data and contents of a particular page data latch of the second memory die; and
storing a result of the bitwise XOR operation at the particular page data latch.

17. The method of claim 16, further comprising, after storing the first data at the first page data latch of the first memory die:
sending a second command and a second data from the controller to the first memory die;
storing, based on the second command, the second data at the first transfer data latch of the first memory die; and
storing, based on the second command, the second data at the second transfer data latch of the second memory die.

18. The method of claim 16, further comprising, based on detecting an event, storing the result of the bitwise XOR operation to a non-volatile memory of the second memory die.

19. The method of claim 16, further comprising after storing the first data to a first word line of the first memory die:
determining that programming of a second word line of the first memory die was not successful; and
recovering the first data based on the result of the bitwise XOR operation.

20. The method of claim 19, wherein the first word line is adjacent to the second word line.
